(19) United States
(12) Patent Application Publication
(10) Pub. No.: US 2025/0272011 A1
(43) Pub. Date: Aug. 28, 2025

(54) DECODER SCHEME FOR REDUCING POWER CONSUMPTION OF READING AND WRITING

(71) Applicant: Silicon Motion, Inc., Hsinchu County (TW)

(72) Inventor: Mao-Ruei Li, Hsinchu City (TW)

(73) Assignee: Silicon Motion, Inc., Hsinchu County (TW)

(21) Appl. No.: 18/892,590

(22) Filed: Sep. 23, 2024

(30) Foreign Application Priority Data
Feb. 23, 2024 (TW) 113106471

(51) Int. Cl. G06F 3/06

(52) U.S. Cl. CPC G06F 3/0625; G06F 3/0655; G06F 3/0679

(57) ABSTRACT

A decoding method of a decoder circuit includes: using a memory circuit to receive input data; using the input data to generate or update a variable-to-check message and a log-likely ratio; converting the variable-to-check message from variable node domain into check node domain to generate a converted variable-to-check message; generating a check-to-variable message according to the converted variable-to-check message; converting the check-to-variable message from check node domain into variable node domain to generate a converted check-to-variable message, so as to calculate and update the variable-to-check message and the log-likely ratio; performing a hard decision according to the log-likely ratio; storing multiple data portions of the input data into multiple storage positions of the memory circuit in response to a decoding calculation schedule; and controlling storage position(s) of the memory circuit to be empty for the shortening setting or puncturing setting.

### BACKGROUND OF THE INVENTION

### 1. Field of the Invention

The present invention relates to a decoding scheme, and more particularly to a decoder circuit, a decoding method, and a flash memory controller.

### 2. Description of the Prior Art

Generally speaking, traditional existing technologies are limited by the impact of process yield, and the memory suppliers will limit the depth and bandwidth of the memories. Thus, the actual memory bandwidth often cannot meet the system-level requirements, and all small physical memories will operate at the same time when each time it is necessary to read and write data based on the system-level requirements. However, in a high-noise environment, such as the iterative decoding calculation of a decoder, it quite consumes power to simultaneously read and write all small physical memories each time.

### SUMMARY OF THE INVENTION

Therefore one of the objectives of the present invention is to provide a decoder circuit, a decoding method, and a flash memory controller, to solve the above-mentioned problems.

According to an embodiment of the present invention, a decoder circuit is disclosed. The decoder circuit comprises a memory circuit, a variable node circuit, a variable-to-check circuit, a check node circuit, a check-to-variable circuit, and a syndrome calculation circuit. The memory circuit is used for receiving and temporarily storing an input data. The variable node circuit, coupled to the memory circuit, is used for receiving data of a specific codeword of the input data to generate or update a variable-to-check message and generate a log-likely ratio to a syndrome calculation circuit. The variable-to-check circuit, coupled to the variable node circuit, is used for converting the variable-to-check message from a variable node domain into a check node domain to generate a converted variable-to-check message. The check node circuit, coupled to the variable-to-check circuit, is used for performing a minimization calculation based on the converted variable-to-check message to generate a check-to-variable message; The check-to-variable circuit, coupled to the check node circuit, is used for converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio. The syndrome calculation circuit, coupled to the variable node circuit, is used for performing a hard decision based on the log-likely ratio to determine whether to flip information of at least one bit in the specific codeword to generate an output codeword. The memory circuit based on the input data, a shortening setting and a puncturing setting is arranged to store multiple data portions of the input data in multiple corresponding storage positions according to a decoding calculation schedule of the decoder circuit, and to respectively free up a space of at least one first storage position for at least one shortened data portion indicated by the shortening setting and free up a space of at least one second storage position for at least one punctured data portion indicated by the puncturing setting.

According to an embodiment of the invention, a decoding method of a decoder circuit is disclosed. The decoding method comprises: providing and using a memory circuit to receive and temporarily store an input data; using a variable node circuit to receive data of a specific codeword of the input data to generate or update a variable-to-check message and generate a log-likely ratio to a syndrome calculation circuit; converting the variable-to-check message from a variable node domain into a check node domain to generate a converted variable-to-check message; performing a minimization calculation based on the converted variable-to-check message to generate a check-to-variable message; converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio; using the syndrome calculation circuit to perform a hard decision based on the log-likely ratio to determine whether to flip information of at least one bit in the specific codeword to generate an output codeword; storing multiple data portions of the input data in multiple corresponding storage positions in response to a decoding calculation schedule of the decoder circuit based on the input data, a shortening setting and a puncturing setting; and, controlling the memory circuit to respectively free up a space of at least one first storage position for at least one shortened data portion indicated by the shortening setting and to free up a space of at least one second storage position for at least one punctured data portion indicated by the puncturing setting.

According to an embodiment of the invention, a flash memory controller is disclosed. The flash memory controller comprises an encoder and a decoder circuit. The encoder is used for performing en encoding operation upon a write data sent from a host device to write the write data into a flash memory. The decoder circuit is used for performing a decoding operation upon a read data read from the flash memory to generate a decoded data. The decoder circuit comprises a memory circuit, a variable node circuit, a variable-to-check circuit, a check node circuit, a check-to-variable circuit, and a syndrome calculation circuit. The memory circuit is used for receiving and temporarily storing an input data. The variable node circuit, coupled to the memory circuit, is used for receiving data of a specific codeword of the input data to generate or update a variable-to-check message and generate a log-likely ratio to a syndrome calculation circuit. The variable-to-check circuit, coupled to the variable node circuit, is used for converting the variable-to-check message from a variable node domain into a check node domain to generate a converted variable-to-check message. The check node circuit, coupled to the variable-to-check circuit, is used for performing a minimization calculation based on the converted variable-to-check message to generate a check-to-variable message; The check-to-variable circuit, coupled to the check node circuit, is used for converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio. The syndrome calculation circuit, coupled to the variable node circuit, is used for performing a hard decision based on the log-likely ratio to determine whether to flip information of at least one bit in the specific codeword to generate an output codeword. The memory circuit based on the input data, a shortening setting and a puncturing setting is arranged to store multiple data portions of the input data in multiple corresponding storage positions according to a decoding calculation schedule of the decoder circuit, and to respectively free up a space of at least one first storage position for at least one shortened data portion indicated by the shortening setting and free up a space of at least one second storage position for at least one punctured data portion indicated by the puncturing setting.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a flash memory controller according to an embodiment of the present invention.

FIG. 2 is a schematic diagram of the ECC decoder shown in FIG. 1 for reconstructing the input data.

FIG. 3 is a circuit diagram of a memory circuit according to an embodiment of the present invention.

FIG. 4 is a schematic diagram of an operation example of the memory circuit shown in FIG. 3 according to an embodiment of the present invention.

FIG. 5 is a schematic diagram of a communication system circuit according to an embodiment of the present invention.

### DETAILED DESCRIPTION

The present invention aims to provide a decoder circuit that can reduce the reading and writing frequency of a channel value memory during an iterative decoding procedure, so as to further reduce the power consumption of reading and writing.

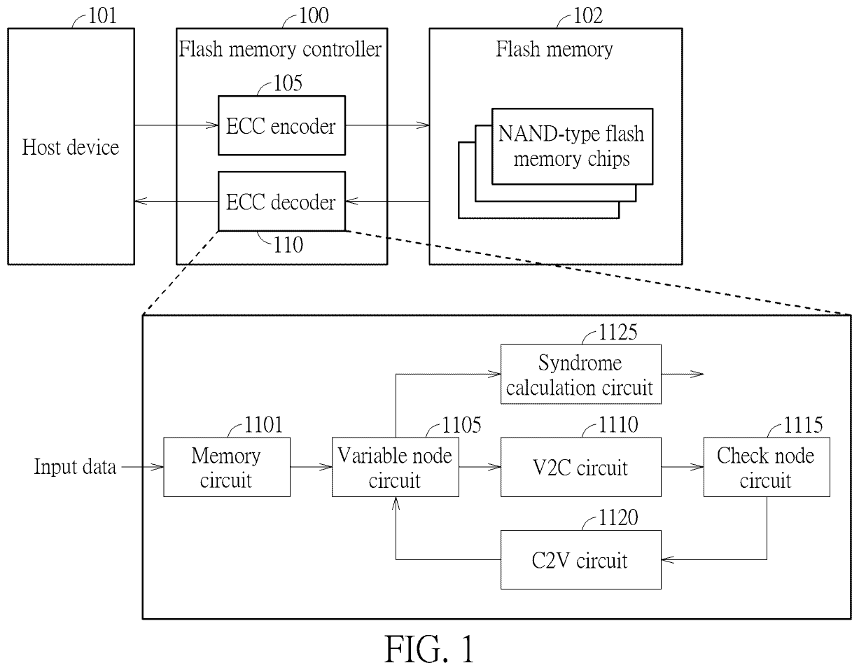

Refer to FIG. 1. FIG. 1 is a block diagram of a flash memory controller 100 according to an embodiment of the present invention. As shown in FIG. 1, the flash memory controller 100 is coupled between a host device 101 and a flash memory 102. The flash memory controller 100 includes an encoder 105 and a decoder circuit 110. The encoder 105 is for example as an error correction code (ECC) encoder. The decoder circuit 110 is for example an ECC decoder. The flash memory 102 includes multiple flash memory chips such as NAND-type flash memory chips. For example, when the host device 101 writes data to one or more flash memory chips in the flash memory 102, the data to be written (for example simply called a write data) will first be sent to the flash memory controller 100. The ECC encoder 105 performs an encoding processing operation (for example, Low-density parity-check code (LDPC) encoding processing, but not limited to) upon the write data to generate an encoded write data, so as to write the encoded write data into one or more flash memory chips of the flash memory 102. In addition, when the host device 101 reads data from one or more flash memory chips in the flash memory 102, the data to be read (for example simply called a read data) will first be sent to the flash memory controller 100. The ECC decoder 110 performs a decoding processing operation (such as LDPC decoding processing, but not limited) upon the read data to generate a decoded read data, so as to transmit the decoded read data into the host device 101. It should be noted that the process of data reading/writing operations may also involve with other data processing operations such as randomization operations and de-randomization operations, etc. The modifications are suitable for the embodiments of the present invention.

As shown in FIG. 1, the ECC decoder 110 is, for example, an LDPC decoder circuit and includes a memory circuit 1101, a variable node circuit 1105, a variable-to-check (V2C) circuit 1110, a check node circuit 1115, a check-to-variable (C2V) circuit 1120, and a syndrome calculation circuit 1125. Specifically, the value of an input data initially received by the ECC decoder circuit 100 can be regarded as a channel value and can be stored in the memory circuit 1101 of the ECC decoder 110. The memory circuit 1101 serves as a channel value memory. In one embodiment, the ECC decoder 100 for example is applied to a storage device, and the value of the received input data is for example the data read from one or more flash memories of the storage device. In another embodiment, the ECC decoder 100 is applied to a communication system, and the value of the received input data is for example the data received from a mobile communication device such as a mobile phone. In addition, the above-mentioned channel value memory 1101 can receive and store the value of the input data in the form of a codeword, and the variable node circuit 1105 reads the input data (i.e. the stored codeword) from the channel value memory 1101. In the following paragraphs, the term “channel value” is used to represent a value received by the ECC decoder 100 and stored in the channel value memory 1101.

In the embodiment of the present invention, one or more codewords are stored in the memory circuit 1101 which is used as the channel value memory. The channel value memory 1101 outputs a fragment of bits of a codeword for each time, e.g. at every processing time cycle. Each iterative decoding calculation of the LDPC decoding operation is used to sequentially process and perform calculations upon multiple fragment of bits (for example, 10 fragments) of a codeword. The number of the multiple fragments of bits in the default setting corresponds to and is equal to the number of variable nodes which is to be processed and calculated in each iterative decoding calculation, e.g. ten variable nodes. In other words, it is required to use ten processing time units to perform relevant decoding calculations for a codeword having ten fragments of bits.

The following briefly describes the concept of an iterative decoding of an LDPC decoding operation. In an iterative decoding (for example, the n-th iterative decoding, and n is a positive integer), when a specific codeword of input data (i.e. a channel value) is received and buffered from the channel value memory 1101, the variable node circuit 1105 generates (or updates) and outputs a variable-to-check message, which is a probability value and also called as Q value, according to the specific codeword into the V2C circuit 1110, and generates (or updates) and outputs a log-likely ratio (i.e. a posterior probability value) into the syndrome calculation circuit 1125. Then, the V2C circuit 1110 performs a format conversion of variable node to check node so as to convert the variable-to-check message (Q value) from a variable node domain to a check node domain to generate a converted variable-to-check message into the check node circuit 1115. The check node circuit 1115 performs a minimization calculation based on one or more converted variable-to-check messages to generate a check-to-variable message (also called an R value which is another probability value) to the C2V circuit 1120. The C2V circuit 1120 is used to perform a format conversion of check node to variable node so as to convert the check-to-variable message (R value) from a check node domain to a variable node domain to generate a converted check-to-variable message into the variable node circuit 1105. The variable node circuit 1105 can perform a sum calculation based on one or more check-to-variable messages (R values, i.e. probability values) transmitted from the C2V circuit 1120 to generate and update the variable-to-check message (Q value), and can perform another sum calculation based on one or more check-to-variable messages (R values, i.e. probability values) transmitted from the C2V circuit 1120 to generate and update the log-likely ratio. The log-likely ratio serves as the value of the posterior probability and is outputted to the syndrome calculation circuit 1125. The generated and updated posterior probability value can be a positive value or a negative value. The syndrome calculation circuit 1125 uses the positive/negative sign of the generated and updated posterior probability value to make a hard decision to determine whether to flip information (‘0’ or ‘1’) of one or more bits in the specific codeword. The syndrome calculation circuit 1125 then calculates a syndrome value based on the result of flipped or not yet flipped information of the codeword (that is, an output data (codeword) may have bits flipped or bits not flipped). In this situation, if the calculated syndrome value is zero, then this indicates that a valid codeword is found, and the iterative decoding calculation can be interrupted and the decoding operation is completed.

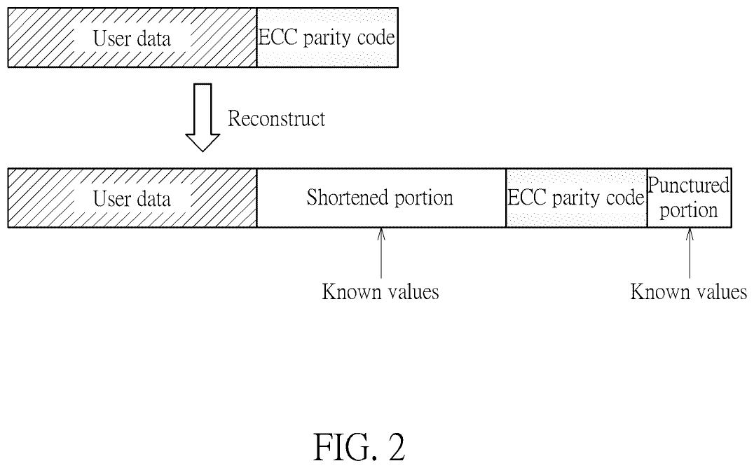

Refer to FIG. 2. FIG. 2 is a schematic diagram of the ECC decoder 110 shown in FIG. 1 reconstructing the input data (such as a specific codeword and is also called a channel value). As shown in FIG. 2, the ECC decoder 110 is used as an LDPC decoder (but not limited to) to receive and process the input data. Since the input data has been shortened or punctured, the ECC decoder 110 therefore backfills a system default value into the shortened/punctured input data to supplement enough bits (e.g., supplementing enough codeword bits) for subsequent decoding applications to perform calculations. For example, the processing of bit shortening or bit puncturing is used in some certain scenarios to shorten or puncture the data's a portion of bits which is not needed to be transmitted, and only the portions of bits which are needed to be transmitted are sent into the ECC decoder 100, so as to maximize the data transmission amount. By doing so, the ECC decoder 100 at the receiver side may use and backfill a system default value to supplement an enough data length.

As shown in FIG. 2, the shortened/punctured input data may include a bit portion that needs to be transmitted, that is, a user data and an ECC parity code. When receiving the input data, the ECC decoder 100 reconstructs the input data, uses a known value (such as a system default value) to backfill the shortened bit portion between the user data and the ECC parity code, and uses a known value (such as a system default value) to backfill and append the punctured bit portion after the ECC parity code to supplement a sufficient number of bits for subsequent iterative decoding calculations.

It should be noted that, when the ECC decoder 100 reconstructs the input data, the ECC decoder 100 does not reconstruct the input data and then store the reconstructed input data into the channel value memory (that is, the memory circuit 1101), and the ECC decoder 100 at first according to the decoding calculation schedule stores and writes the received input data, that has not been reconstructed, into the memory circuit 1101 and frees up the space of one or more storage positions for at least one shortened/punctured data portion. For example, according to the input data, a shortening setting, and a puncturing setting, the memory circuit 1101 based on a decoding calculation schedule of the decoder circuit 100 can store multiple data portions of the input data into multiple corresponding storage positions of the memory circuit 1101, and respectively frees up the space of at least one first storage position for at least one shortened data portion indicated by the shortening setting and frees up the space of at least one second storage position for at least one punctured data portion indicated by the puncturing setting. In this way, when the ECC decoder 100 (for example the variable node circuit 1105) performs decoding-related calculations, it is only required to sequentially read the multiple data portions of the input data that have not been reconstructed from the memory circuit 1101 and to directly use the system default value as the data portion that is shortened or punctured. Accordingly, the number and frequency of reading/writing for large amounts of data of the memory circuit 1101 can be reduced, and more power can be saved.

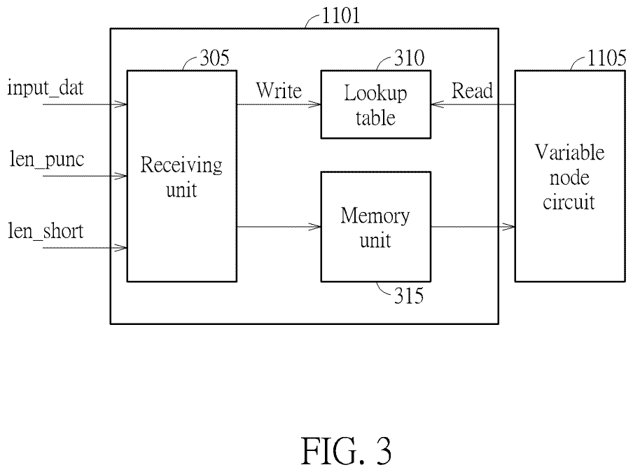

Refer to FIG. 3. FIG. 3 is a circuit diagram of the memory circuit 1101 according to an embodiment of the present invention. As shown in FIG. 3, the memory circuit 1101 includes a receiving unit 305, a memory unit 315, and a lookup table 310. These circuits/units can be implemented by using hardware or firmware units. The receiving unit 305 is, for example, a receiver or a receiving module, and is used to receive a shortened input data input_dat and to receive and process a shortening setting len_short and a puncturing setting len_punc. The lookup table 310 is coupled to the receiving unit 305. The memory unit 315 is coupled to the receiving unit 305 and used to store the multiple data portions (such as multiple codewords, multiple bit segments, etc.) of the input data.

For example, when receiving the user data and ECC parity code (i.e. input data input_dat) shown in FIG. 2, the receiving unit 305 can know the decoding calculation schedule of the decoder circuit 100 according to a shortening setting len_short and a puncturing setting len_punc, so as to know and obtain the number (such as the number of codewords, the number of bit fragments, etc.) of shortened data portions between the user data and the ECC parity code and the number (such as the number of codewords, the number of bit fragments, etc.) of punctured data portions after the ECC parity code. The shortening setting len_short and puncturing setting len_punc can be preset or predetermined according to the iterative decoding algorithm adopted by the decoder circuit 100.

As mentioned above, according to the input data input_dat, the shortening setting len_short, and the puncturing setting len_punc the memory circuit 1101 based on the decoding calculation schedule can store multiple data portions of the input data input_dat in multiple corresponding storage positions of the memory circuit 1101, and can respectively free up the space of at least one first storage position for at least one shortened data portion indicated by the shortening setting and free up the space of at least one second storage position for at least one punctured portion indicated by the puncturing setting. When the receiving unit 305 stores the multiple data portions of the input data input_dat in the multiple corresponding storage positions of the memory unit 315 according to the decoding calculation schedule, the receiving unit 305 simultaneously generates and notes a first information (for example bit ‘1’, but not limited to) in multiple fields corresponding to the multiple corresponding storage positions in the lookup table 310. When the receiving unit 305 controls the memory unit 315 to free up the space of at least one first storage position for at least one shortened data portion indicated by the shortening setting, the receiving unit 305 simultaneously generates and notes a second information (such as bit ‘0’, but not limited to) in at least one field in the lookup table 310 corresponding to the at least one shortened data portion. In addition, when the receiving unit 305 controls the memory unit 315 to free up the space of at least one second storage position for the at least one punctured data portion indicated by the puncturing setting, the receiving unit 305 simultaneously generates and notes the second information in at least one field in the lookup table 310 corresponding to the at least one punctured data portion.

In other words, during the actual reception of data bits, when the user data has been received but the ECC parity code has not been received, (i.e. this is the time when the shortened data bits should have been processed), the receiving unit 305 is arranged to skip the write operation for the memory unit 315, i.e. controlling the memory unit 315 not to perform the write operation and to free up the number of storage positions corresponding to the number of shortened data portions. In this situation, the result (i.e. bit ‘0’) of not performing the write operation is written into one or more corresponding fields in the lookup table 310. Therefore, the lookup table 310 can record the results of whether the write operation is performed for the memory unit 315 or not at different addresses. When the input data input_dat is received, how matter how it is not written into the memory unit 315 due to the internal design of the decoder or other reasons, the lookup table 310 makes a record of one or more storage positions that have not been written.

When the subsequent circuits (such as the variable node circuit 1105) of the ECC decoder 100 needs to sequentially read the data stored in the memory unit 315, the variable node circuit 1105 at first may read the content recorded in the lookup table 310 to determine whether to read the data stored in the memory unit 315 or to use the system default value (such as bit ‘0’, but not limited to) to supplement the sufficient number of bits for the iterative decoding calculation without reading the memory unit 315. In other words, the variable node circuit 1105 for example reads the information noted/marked in a specific field from the lookup table 310 to determine whether to retrieve the information of a specific data portion from a specific storage position corresponding to the specific field in the memory unit 315 to perform a decoding calculation. When the information noted/marked in the specific field read by the variable node circuit 1105 from the lookup table 310 indicates the first information (for example bit ‘1’), the variable node circuit 1105 reads the specific data portion from the specific storage position corresponding to the specific field in the memory unit 315 to perform the decoding calculation. When the information noted/marked in the specific field read by the variable node circuit 1105 from the lookup table 310 indicates the second information (for example bit ‘0’), the variable node circuit 1105 directly uses a reference data portion having a preset reference value (e.g. bit ‘0’) is used to perform the decoding calculation without reading the memory unit 315.

In this way, during the iterative decoding calculation, for the shortened/punctured bits, the memory circuit 1101 can decide not to read the memory unit 315 (that is, close the operation of the variable node circuit 1105 controlling and reading the memory unit 315) and use the system default value (such as bit ‘0’, but not limited to) to directly supplement the sufficient number of bits for the iterative decoding calculation, to thereby significantly reducing the number and frequency for reading the memory unit 315 and effectively reducing the power consumption of accessing physical memories.

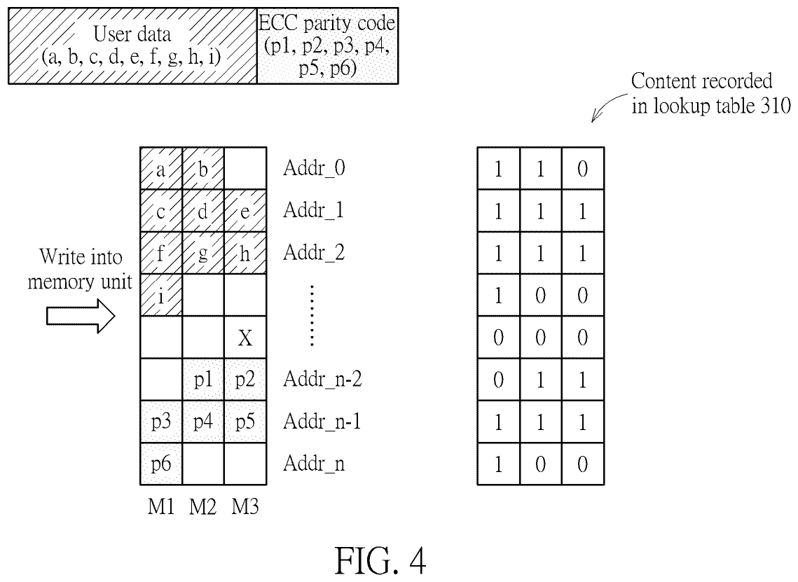

Refer to FIG. 4. FIG. 4 is a schematic diagram of an operation example of the memory circuit 1101 shown in FIG. 3 according to an embodiment of the present invention. As shown in FIG. 4, an input data with insufficient bit length received from the outside includes, for example, a user data and an ECC parity code. The user data includes multiple data portions a˜i in sequence, and the ECC parity code includes multiple data portions p1˜p6 in sequence. Each data portion can be a codeword unit, a fragment bit unit, or other data bit unit sizes, and is not limited.

In addition, the memory unit 315 is, for example, a memory macro and is composed of multiple physical sub-memories. For example, it is composed of three physical sub-memories M1, M2, and M3. The three physical sub-memories M1, M2, and M3 are controlled and written by the receiving unit 305. For example, when the system requires a data width of 544 bits and needs to store a total of 512 entries of data, the system may need to use a hardware memory with a depth of 512 bits and a bandwidth of 544 bits to store the information data. In fact, due to the influence of process yield, memory suppliers will limit the depth and bandwidth, so the actual memory bandwidth often cannot meet the requirements of the system. For example, ideal it may needed to generate a static random access memory (SRAM) with a depth of 512 bits, but however the actual implemented memory can only provide a maximum width of 224 bits. Therefore, in practice, the memory unit 315 uses multiple small physical static random access memory SRAMs for implementation in order to achieve a hardware memory with a depth of 512 bits and a bandwidth of 544 bits. For example, the memory unit 315 may utilize two 512×224 and one 512×96 SRAMs to combine the required size of hardware memory. In the embodiments of the present invention, each small physical memory is regarded as a single memory entity at the system level. When one or some small memories are not needed to be read or written, the one or some small memories can be controlled not to operate at the same time, so that the number/frequency of reading and writing can be reduced.

As shown in FIG. 4, the memory unit 315 uses, for example, three physical sub-memories M1, M2, and M3 to store data. The three physical sub-memories, for example, respectively correspond to the three columns shown in the left half of FIG. 4. The receiving unit 305 writes the input data input_dat into different physical sub-memories of the memory unit 315 in an address order according to the shortening setting len_short and the puncturing setting len_punc. For example, for writing of a specific address, the receiving unit 305 writes a specific data portion of the input data into a storage position of a specific physical sub-memory in the multiple physical sub-memories, and controls the memory unit 315 to close the write operation of another specific physical sub-memory and to free up the space of a storage position of the another specific physical sub-memory for the shortening setting len_short or the puncturing setting len_punc. When deciding to perform a write operation for a certain address of a physical sub-memory, the receiving unit 305 is arranged to correspondingly make a record of ‘1’ in a corresponding field of the lookup table 310 to indicate that the certain address of the physical sub-memory has been written. On the contrary, when the receiving unit 305 decides not to perform a write operation for a certain address of the physical sub-memory, the receiving unit 305 correspondingly makes a record of ‘0’ in a corresponding field of the lookup table 310 to indicate that the certain address in the physical sub-memory has not yet been written.

For example, for address Addr_0, data portions a and b are written to two storage positions (such as storage units) at address Addr_0 of physical sub-memories M1 and M2 respectively at the same time, and the shortening setting len_short indicates that originally there is a data portion, which is not needed to be transmitted and should be shortened, between the data portions b and c. Thus, in this situation, a storage position at address Addr_0 of the physical sub-memory M3 will not be written, that is, the storage position at the address Addr_0 of physical sub-memory M3 is freed up, and the writing operation of the physical sub-memory M3 is not started at this time. The receiving unit 305 writes and makes a record of ‘1’, ‘1’, ‘0’ in the corresponding fields of the lookup table 310. Then, for the address Addr_1, the data portions c, d, and e are simultaneously and respectively written to the three storage positions at the address Addr_1 of the physical sub-memories M1, M2, and M3. At this time, the receiving unit 305 writes and makes a record of ‘1’, ‘1’, ‘1’ in the corresponding fields of lookup table 310. Then, the data portions f, g, and h are written to the three storage positions at the address Addr_2 of the physical sub-memory M1, M2, and M3 respectively and simultaneously. At this time, the receiving unit 305 also writes and makes a record of ‘1’, ‘1’, ‘1’ in the corresponding fields of the lookup table 310.

The data portion i is, for example, the last data portion of the user data and is written to a storage position at the address Addr_3 (not shown) of the physical sub-memory M1, and the shortening setting len_short indicates that originally there are multiple data portions, which are not needed to be transmitted and should be shortened, between the data portion i and the data portion p1; the multiple data portions may include a don't care (represented by ‘X’) data portion. Thus, in this situation, the receiving unit 305 does not perform the write operation for the storage positions of address Addr_3 of physical sub-memory M2 and M3. That is, the storage positions of address Addr_3 of physical sub-memory M2 and M3 are freed up and the write operation of the physical sub-memory M2 and M3 are not started at this time, and the receiving unit 305 writes and makes a record of ‘1’, ‘0’, ‘0’ in the corresponding fields of the lookup table 310. Then, the receiving unit 305 does not perform a write operation for the storage positions of one or more subsequent corresponding addresses of the physical sub-memories M1, M2, and M3 (prior to the address Addr_n−2). The subsequent storage positions corresponding to one or more multiple addresses are also freed up, and in this situation the writing operations of the physical sub-memories M1, M2, and M3 will not be started. Correspondingly, the receiving unit 305 writes and makes a record of ‘0’, ‘0’, ‘0’ in the corresponding fields of the lookup table 310.

Then, according to the shortening setting len_short, the receiving unit 305 can obtain and know that the last one data portion, which is not needed to be transmitted and prior to the data portion p1, is associated with the storage position corresponding to the address Addr_n−2 of the physical sub-memory M1, and the receiving unit 305 respectively and simultaneously writes the data portions p1 and p2 into the storage positions at the address Addr_n−2 of the physical sub-memories M1 and M2. Therefore, in this situation, the storage position at the address Addr_n−2 of the physical sub-memory M1 is freed up and the write operation of the physical sub-memory M1 is not activated. The storage positions at the address Addr_n−2 of the physical sub-memories M1 and M2 are to be written. Correspondingly, the receiving unit 305 writes and makes a record of ‘0’, ‘1’, ‘1’ in the corresponding fields of the lookup table 310. Then, the receiving unit 305 writes the data portions p3, p4, and p5 to the storage positions at the addresses Addr_n−1 of the physical sub-memories M1, M2, and M3 respectively at the same time, and correspondingly the receiving unit 305 writes and makes a record of ‘1’, ‘1’, ‘1’ in the corresponding fields of the lookup table 310. Then, the receiving unit 305 writes the data portion p6 to the storage position at the address Addr_n of the physical sub-memory M1, and the receiving unit 305 can know that the data portion p6 is the last data portion of the ECC parity code, and according to the puncturing setting len_punc it can obtain and know that originally there are two data portions, which are not needed to be transmitted and can be punctured, later than the data portion p6. Therefore, when the receiving unit 305 writes the data for the address Addr_n, the storage positions at the addresses Addr_n of the physical sub-memories M2 and M3 are freed up, and in this situation the write operations of the two physical sub-memories M2 and M3 will not be started at this time. Correspondingly, the receiving unit 305 writes and makes a record of ‘1’, ‘0’, ‘0’ in the corresponding fields of the lookup table 310.

It should be noted that the contents of the shortening setting len_short and the puncturing setting len_punc can be determined according to the iterative decoding algorithm used by the ECC decoder 110, and for example can be determined in advance according to the used iterative decoding algorithm or may be determined by other circuit components such as variable node circuit 1105 in the ECC decoder 110. This is not intended to be a limitation of the invention.

When the ECC decoder 100 at the receiver side receives an input data, the receiving unit 305 can obtain a decoding calculation schedule from the contents of the shortening setting len_short and the puncturing setting len_punc. According to the decoding calculation schedule, the receiving unit 305 can directly write the received input data into one or more corresponding storage positions in one or more physical sub-memories of the memory unit 315, and frees up one or more corresponding storage positions for the shortening setting len_short and/or the delete setting len_punc. That is, for the shortened/punctured data portion, the receiving unit 305 does not perform the data reconstruction to write the reconstructed data into one or more physical sub-memories of the memory unit 315, but it will use the lookup table 310 as a note table to note whether each address of each of multiple physical sub-memories has been written or not. When the ECC decoder 100 starts to read the physical sub-memory for decoding operation, it at first reads the information recorded in the lookup table. If a corresponding storage position has not yet been written, the ECC decoder 100 will directly use a known value (such as bit ‘0’, but not limited to) to supplement the originally shortened or punctured data portion(s) so that the decoding operation can be performed smoothly and correctly. If the storage position has been written, the ECC decoder 100 reads a data portion from a physical sub-memory corresponding to the storage position, which is identical to the normal decoding process. In this way, when a large amount of data in the error correction code can be shortened or punctured, the writing time of the physical sub-memories and the power consumption can be greatly reduced by using the method proposed in the embodiment of the present invention. This can also significantly reduce the required read power consumption when reading the physical sub-memories, so that the power consumption of overall memory can be reduced.

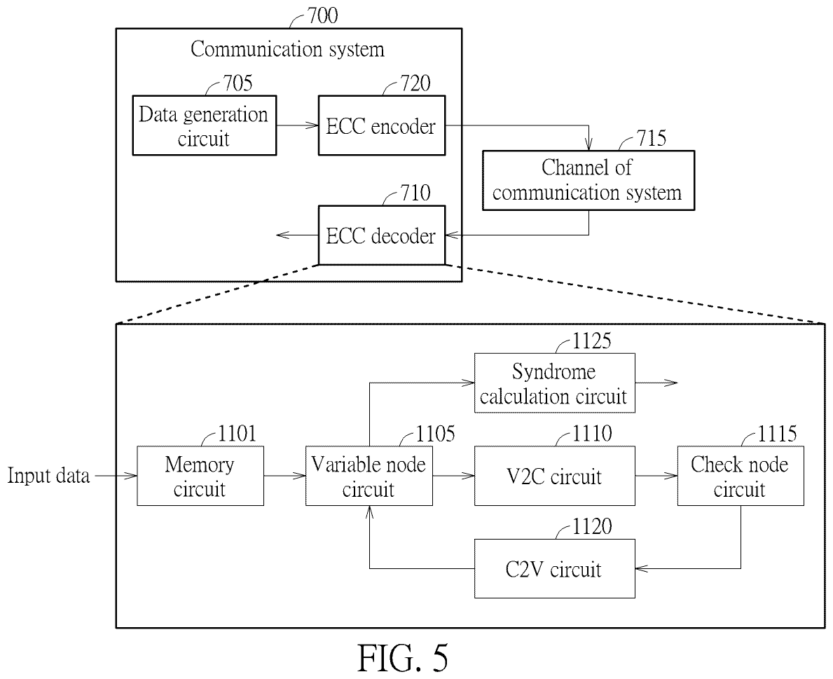

Similarly, the above-mentioned ECC decoder can also be applied in a communication system. Refer to FIG. 5. FIG. 5 is a schematic diagram of a communication system circuit 700 according to an embodiment of the present invention. As shown in FIG. 5, the communication system circuit 500 is, for example, a wireless transceiver and includes a data generation circuit 705, an ECC encoder 720, and an ECC decoder 710. The data generation circuit 705 is used to generate a specific data such as a specific codeword. The ECC encoder 720 performs ECC encoding (such as an LDPC encoding operation) upon the specific codeword to generate an encoded codeword, and transmits the encoded codeword to a communication system channel 715 such as a wireless transmission medium (but not limited to). Then the ECC decoder 710 is used to receive the encoded codeword and perform a decoding operation upon the encoded codeword to perform an iterative decoding calculation for multiple times to generate a correct codeword data. The ECC decoder 710 is, for example, an LDPC decoder circuit and includes a memory circuit 1101, a variable node circuit 1105, a V2C circuit 1110, a check node circuit 1115, a C2V circuit 1120, and a syndrome calculation circuit 1125; the operations and functions are the same as those of the aforementioned circuit components with the same numbers and will not be repeated again.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A decoder circuit, comprising:
a memory circuit, for receiving and temporarily storing an input data;
a variable node circuit, coupled to the memory circuit, for receiving data of a specific codeword of the input data to generate or update a variable-to-check message and generate a log-likely ratio to a syndrome calculation circuit;
a variable-to-check circuit, coupled to the variable node circuit, for converting the variable-to-check message from a variable node domain into a check node domain to generate a converted variable-to-check message;
a check node circuit, coupled to the variable-to-check circuit, for performing a minimization calculation based on the converted variable-to-check message to generate a check-to-variable message;
a check-to-variable circuit, coupled to the check node circuit, for converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio; and
the syndrome calculation circuit, coupled to the variable node circuit, for performing a hard decision based on the log-likely ratio to determine whether to flip information of at least one bit in the specific codeword to generate an output codeword;
wherein the memory circuit based on the input data, a shortening setting and a puncturing setting is arranged to store multiple data portions of the input data in multiple corresponding storage positions according to a decoding calculation schedule of the decoder circuit, and to respectively free up a space of at least one first storage position for at least one shortened data portion indicated by the shortening setting and free up a space of at least one second storage position for at least one punctured data portion indicated by the puncturing setting.

2. The decoder circuit of claim 1, wherein the memory circuit comprises:
a receiving unit, for receiving the input data, the shortening setting, and the puncturing setting;
a lookup table, coupled to the receiving unit; and
a memory unit, coupled to the receiving unit, for storing the multiple data portions of the input data;
when the receiving unit stores the multiple data portions of the input data in the multiple corresponding storage positions within the memory unit according to the decoding calculation schedule, the receiving unit is arranged to simultaneously generate and note a first information in multiple fields corresponding to the multiple corresponding storage positions in the lookup table; when the receiving unit controls the memory unit to free up the space of the at least one first storage position for the at least one shortened data portion indicated by the shortening setting, the receiving unit is arranged to simultaneously generate and note a second information in at least one field corresponding to the at least one shortened data portion in the lookup table; and, when the receiving unit controls the memory unit to free up the space of the at least one second storage position for the at least one punctured data portion indicated by the puncturing setting, the receiving unit is arranged to simultaneously generate and note the second information in at least one field corresponding to the at least one punctured data portion in the lookup table.

3. The decoder circuit of claim 2, wherein the variable node circuit reads information noted in a specific field from the lookup table to determine whether to retrieve a specific data portion from a specific storage position of the memory circuit which corresponds to the specific field, to perform a decoding calculation.

4. The decoder circuit of claim 3, wherein when the information noted in the specific field, read by the variable node circuit from the lookup table, indicates the first information, the variable node circuit is arranged to read the specific data portion from the specific storage position in the memory unit corresponding to the specific field to perform the decoding calculation; and, when the information noted in the specific field, read by the variable node circuit from the lookup table, indicates the second information, the variable node circuit is arranged to directly use a reference data portion having a preset reference value to perform the decoding calculation without reading the memory unit.

5. The decoder circuit of claim 4, wherein the memory unit comprises multiple physical sub-memories, and writing of the multiple physical sub-memories is controlled by the receiving unit; for writing of a specific address, the receiving unit is arranged to write a specific data portion of the input data into a storage position of a specific physical sub-memory among the multiple physical sub-memories, and to control the memory unit to close a writing operation of another specific physical sub-memory and to free up a space of a storage position of the another specific physical sub-memory for the shortening setting or the puncturing setting.

6. A decoding method of a decoder circuit, comprising:
providing and using a memory circuit to receive and temporarily store an input data;
using a variable node circuit to receive data of a specific codeword of the input data to generate or update a variable-to-check message and generate a log-likely ratio to a syndrome calculation circuit;
converting the variable-to-check message from a variable node domain into a check node domain to generate a converted variable-to-check message;
performing a minimization calculation based on the converted variable-to-check message to generate a check-to-variable message;
converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio;
using the syndrome calculation circuit to perform a hard decision based on the log-likely ratio to determine whether to flip information of at least one bit in the specific codeword to generate an output codeword;
storing multiple data portions of the input data in multiple corresponding storage positions in response to a decoding calculation schedule of the decoder circuit based on the input data, a shortening setting and a puncturing setting; and
controlling the memory circuit to respectively free up a space of at least one first storage position for at least one shortened data portion indicated by the shortening setting and to free up a space of at least one second storage position for at least one punctured data portion indicated by the puncturing setting.

7. The decoding method of claim 6, further comprising:
using a receiving unit to receive the input data, the shortening setting, and the puncturing setting;
providing a lookup table;
using a memory unit to store the multiple data portions of the input data;
when the receiving unit stores the multiple data portions of the input data in the multiple corresponding storage positions within the memory unit according to the decoding calculation schedule, simultaneously generating and noting a first information in multiple fields corresponding to the multiple corresponding storage positions in the lookup table;
when the receiving unit controls the memory unit to free up the space of the at least one first storage position for the at least one shortened data portion indicated by the shortening setting, simultaneously generating and noting a second information in at least one field corresponding to the at least one shortened data portion in the lookup table; and
when the receiving unit controls the memory unit to free up the space of the at least one second storage position for the at least one punctured data portion indicated by the puncturing setting, simultaneously generating and noting the second information in at least one field corresponding to the at least one punctured data portion in the lookup table.

8. The decoding method of claim 7, further comprising:
reading information noted in a specific field from the lookup table to determine whether to retrieve a specific data portion from a specific storage position of the memory circuit which corresponds to the specific field, to perform a decoding calculation.

9. The decoding method of claim 8, further comprising:
when the information noted in the specific field, read by the variable node circuit from the lookup table, indicates the first information, reading the specific data portion from the specific storage position in the memory unit corresponding to the specific field to perform the decoding calculation; and
when the information noted in the specific field, read by the variable node circuit from the lookup table, indicates the second information, directly using a reference data portion having a preset reference value to perform the decoding calculation without reading the memory unit.

10. The decoding method of claim 9, wherein the memory unit comprises multiple physical sub-memories, and writing of the multiple physical sub-memories is controlled by the receiving unit; and the method further comprises:
for writing of a specific address, using the receiving unit to write a specific data portion of the input data into a storage position of a specific physical sub-memory among the multiple physical sub-memories, and to control the memory unit to close a writing operation of another specific physical sub-memory and to free up a space of a storage position of the another specific physical sub-memory for the shortening setting or the puncturing setting.

11. A flash memory controller, comprising:
an encoder, for performing en encoding operation upon a write data sent from a host device to write the write data into a flash memory; and
a decoder circuit, for performing a decoding operation upon a read data read from the flash memory to generate a decoded data, and the decoder circuit comprises:
a memory circuit, for receiving and temporarily storing the read data as an input data;
a variable node circuit, coupled to the memory circuit, for receiving data of a specific codeword of the input data to generate or update a variable-to-check message and generate a log-likely ratio to a syndrome calculation circuit;
a variable-to-check circuit, coupled to the variable node circuit, for converting the variable-to-check message from a variable node domain into a check node domain to generate a converted variable-to-check message;
a check node circuit, coupled to the variable-to-check circuit, for performing a minimization calculation based on the converted variable-to-check message to generate a check-to-variable message;
a check-to-variable circuit, coupled to the check node circuit, for converting the check-to-variable message from the check node domain to the variable node domain to generate a converted check-to-variable message, to make the variable node circuit based on the converted check-to-variable message perform a sum calculation to update the variable-to-check message and performing another sum calculation to update the log-likely ratio; and
the syndrome calculation circuit, coupled to the variable node circuit, for performing a hard decision based on the log-likely ratio to determine whether to flip information of at least one bit in the specific codeword to generate an output codeword;
wherein the memory circuit based on the input data, a shortening setting and a puncturing setting is arranged to store multiple data portions of the input data in multiple corresponding storage positions according to a decoding calculation schedule of the decoder circuit, and to respectively free up a space of at least one first storage position for at least one shortened data portion indicated by the shortening setting and free up a space of at least one second storage position for at least one punctured data portion indicated by the puncturing setting.
